(19) United States
(12) Patent Application Publication
(10) Pub. No.: US 2010/0283110 A1
(43) Pub. Date: Nov. 11, 2010

(54) INTEGRATED SENSOR CHIP UNIT

(75) Inventors: Robert Bauer, Moosach (DE); Jochen Von Hagen, Kolbermoor (DE)

Correspondence Address: BRINKS HOFER GILSON & LIONE/INFINEON;INFINEON, PO BOX 10395, CHICAGO, IL, 60610, US

(73) Assignee: Infineon Technologies AG

(21) Appl. No.: 12/838,202

(22) Filed: Jul. 16, 2010

Related U.S. Application Data
(62) Division of application No. 11/329,981, filed on Jan. 10, 2006.
Application No. 11/329,981 is a continuation of application No. PCT/EP2004/051394, filed on Jul. 7, 2004.

(30) Foreign Application Priority Data
Jul. 19, 2003 (DE) 103 32 878.5

(51) Int. Cl. H01L 29/66

(52) U.S. Cl. 257/414; 257/E29.166

(57) ABSTRACT

An integrated sensor chip unit and fabrication method includes a measured-value pickup for determining measurement data and a circuit arrangement for enabling a wireless power supply and interrogation of the measurement data. The measured-value pickup is formed as an integratable sensor, and the circuit arrangement is formed as an integrated semiconductor circuit module. The sensor and the semiconductor circuit module are mechanically and electrically conductively connected to one another using one or more microsystems engineering techniques.

### PRIORITY CLAIM

This application is a divisional application of U.S. patent application Ser. No. 11/329,981 filed on Jan. 10, 2006, which is a continuation of International Application PCT/EP2004/051394 filed on Jul. 7, 2004, which claims priority to German Patent Application DE 103 32 878.5, filed on Jul. 19, 2003, all of which are incorporated by reference in their entirety.

### TECHNICAL FIELD

The present invention relates to a sensor module. In particular, the present invention relates to a measured-value pickup that determines measurement data and a circuit arrangement that enables wireless power supply and interrogation of the measurement data.

### BACKGROUND

Different types of sensors are known that are implanted into humans. Some of these sensors operate without cables, i.e. both the measured-value read-out and the power supply are effected in wireless fashion. One example of such a sensor is disclosed in German utility model DE 201 21 388 U1. In this reference, the sensor contains a deformable membrane and a counterelectrode, which are micropatterned and form a capacitance of a resonant circuit. However, an evaluation circuit is not integrated into the sensor.

In another example, German utility model DE 202 02 131 U1 describes a system for continuously monitoring biometric data of a living organism. It provides a sensor having a transponder and an interrogation station separate from the evaluation unit. The sensor again does not have an evaluation circuit.

DE 43 41 903 A1 describes a device which is suitable for continuously measuring the pressure, the flow rate, the temperature, and potentials and currents in bodies or organs of humans and animals. The device described therein communicates the measured values or measurement signals without cabling percutaneously (that is to say through the skin) to a receiver unit situated outside the body, which receiver unit processes and displays the measurement signals.

U.S. Pat. No. 5,711,861 discloses an electrochemical sensor whose signals are transmitted to an external receiver in wirelessly by means of a transmitter and are evaluated by means of a computer.

None of these sensors contain conditioning circuits as they would then occupy excessively large volumes. Thus, disturbances can occur during signal transmission. For the weak signals of the measured-value pickups, it is outside the body that amplification and conditioning are performed as the corresponding circuits are thus disposed. Implanting complex evaluation circuits in patients' bodies would be unpleasant and difficult to carry out on the patients on account of the large volumes.

### BRIEF DESCRIPTION OF THE DRAWINGS

The present invention is illustrated by way of example and not limited to the accompanying figures in which like references indicate similar elements. Exemplary embodiments will be explained in the following text with reference to the attached drawings, in which:

FIG. 1 shows a highly schematic sensor chip according to the invention;

FIG. 2 shows a further sensor chip according to the invention in side view;

FIG. 3 shows the plan view of a sensor chip in accordance with FIG. 2 in highly schematic fashion;

FIG. 4 shows a further exemplary embodiment of a sensor chip in side view; and

FIG. 5 shows a further variant of an application of a sensor chip according to the invention.

Skilled artisans appreciate that elements in the figures are illustrated for simplicity and clarity and have not necessarily been drawn to scale.

### DETAILED DESCRIPTION

A measured-value pickup is formed as an integratable sensor that contains evaluation electronics. A circuit arrangement for enabling a wireless power supply and interrogation of the measurement data is embodied as an integrated semiconductor circuit module. The sensor and the semiconductor circuit module are mechanically and electrically conductively connected to one another to form an integrated sensor chip unit using microsystems engineering means. Thus, generated measurement signals can be transmitted wirelessly after having already been conditioned. In this case, the determining size is the sensor. This permits the sensor to be small, have improved reliability, and be capable of transmitting already digitized measurement signals. As a result, the susceptibility of the sensor to interference decreases and the reliability in obtaining measured values concomitantly increases.

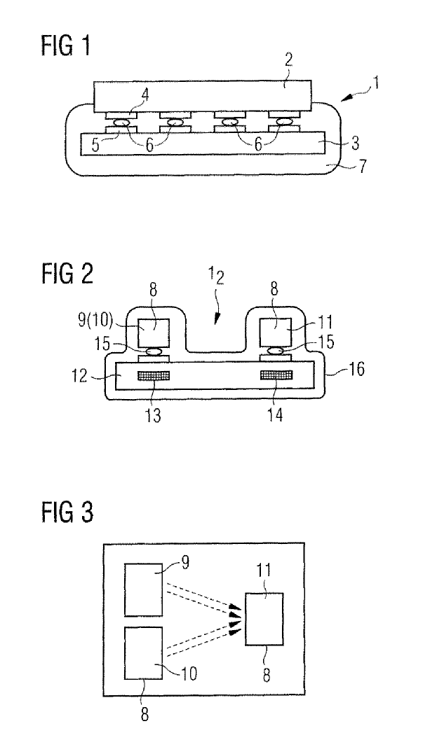

FIG. 1 illustrates an integrated sensor chip unit 1 serving for determining the glucose content in the blood of a living organism. Sensors 2 for measuring the glucose content in blood are well known to one of skill in the art. Such sensors are based, e.g. on capacitance measurements. A complex circuit arrangement is used to condition the signals generated in this way. Electronics can be made very small by using integrated circuits and ultimately lead to an integrated circuit in the form of an integrated semiconductor circuit module 3.

The sensor 2 and the integrated semiconductor circuit module 3 are connected to one another using microsystems engineering means. This connection is effected electrically and mechanically, thus giving rise to an integrated sensor chip unit 1. The measured-value pickup 2 is embodied using nanotechnology and, in the same way as the integrated semiconductor circuit module 3, uses only a very small volume.

A connection in the manner of a flip-chip method is shown as an example of the connection of the measured-value pickup 2 to the integrated semiconductor circuit module 3. Flip-chip connection is a technology in which semiconductor chips, on which small solder balls (bumps) are situated, are mounted directly onto the circuit board without a housing. In order to fix the placed component on the circuit board, only flux is applied. The flux initially acts as an adhesive and evaporates during the subsequent soldering process. The designation flip-chip stems from the fact that the chip lies with the small solder balls upward and is turned (flipped) prior to placement. This technique is explained for example on the Internet page of the company “Binder Elektronik GmbH” http://www.binder-elektronic.de/.

While flip-chip bonding has been shown, other technologies of microsystems engineering can also be employed. Ball wedge bonding is another method by means of which gold wire bonding connections can be produced and the integratable components can thus be constructed using chip-on-board technology (COB). Alternatively, gold stud bumps may be placed onto silicon carriers. These stud bump flip-chips can then be mounted by means of conductive or snap-cure adhesives. This is particularly ideal for small series.

The microsystems engineering is applied directly such that a measured-value pickup (sensor 2) is not connected on a circuit board, but rather directly to the integrated semiconductor circuit module 3 containing the entire evaluation electronics for the measured-value pickup (sensor 2). As a result of this integration step, the volume of the integrated sensor chip unit can be significantly reduced.

In order to produce the connection, both the sensor 2 and the semiconductor circuit module 3 contain connection areas in the form of pads 4 and 5. Using the pads 4 and 5, it is possible to produce an intimate metallic connection between the components—sensor 2 and semiconductor circuit module 3. Solder balls 6 are in each case arranged between the pads 4 and 5. When joining together the sensor 2 and semiconductor circuit module 3 in accordance with microsystems engineering, the small solder balls 6 melt under the influence of heat and/or pressure, so that an intimate metallic connection is produced between the sensor 2 and semiconductor circuit module 3. Consequently, after the combining operation, the unit measured-value pickup/integrated semiconductor circuit module 2/3 forms an integrated sensor chip unit 1. The integrated sensor chip unit 1 is provided with an encapsulation 7 so that it can be implanted into an animal or body such as a human body.

FIG. 2 illustrates a side view of another embodiment of an integrated sensor chip unit 1₂. FIG. 3 shows the associated plan view of this schematic embodiment. A sensor 8 is shown in FIGS. 2 and 3. The sensor 8 can be used to measure the concentration of the oxygen content in the blood of a living organism. The measured-value pickup (sensor 8) has at least two light-emitting diodes 9 and 10. The light-emitting diodes 9 and 10 emit light of different spectra; by way of example, one operates in the red region (at about 700-800 nm) and the other in the infrared region (above about 800 nm). Furthermore, the measured-value pickup (sensor 8) contains a photodiode 11, which receives light emissions of the light-emitting diodes 9 and 10.

Analogous to the embodiment of FIG. 1, the evaluation electronics are situated in an integrated semiconductor circuit module 12. The integrated semiconductor circuit module 12 also has elements such as coils 13 and 14 for power and data transmission. The integrated sensor chip unit 1₂ shown in FIGS. 2 and 3, containing a measured-value pickup 8 and a semiconductor circuit module 12, is also joined together by means of small solder balls 15 in a manner similar to the integrated sensor chip unit 1 in the embodiment shown in FIG. 1. Similarly, the components can be joined using flip-chip technology known from microsystems engineering. The integrated sensor chip unit 1₂ is also provided with an encapsulation 16, so that it is extremely small and can readily be implanted in a living organism.

In the embodiments shown in FIGS. 1-3, the semiconductor circuit module 3 and 12 contains coils for power and data transmission. This permits the measurement data of the integrated sensor chip unit 1 and 1₂ to be interrogated contactlessly from outside the body of the living organism. This contactless transmission of measurement data is known per se, but becomes possible even more simply and primarily more reliably by virtue of the small size of the integrated sensor chip units in FIGS. 1-3 since the conditioning circuit for the measurement data is already situated in the semiconductor circuit module 3 or 12 which is part of the integrated sensor chip unit 1 or 1₂, respectively.

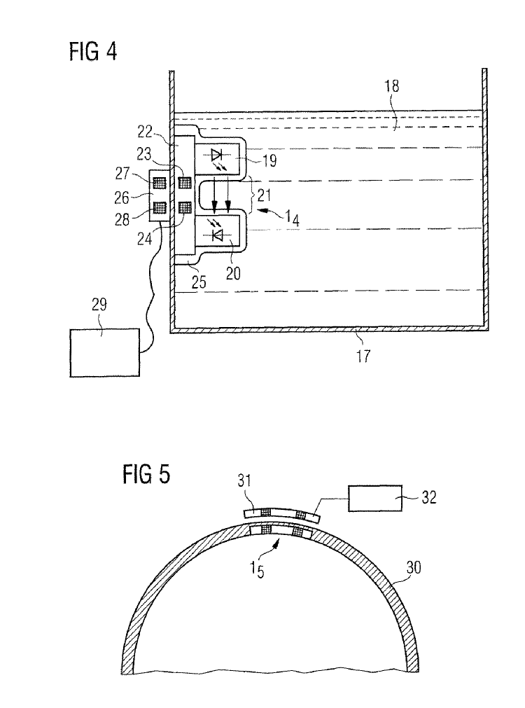

Another embodiment is illustrated in FIG. 4. A container 17 contains a liquid 18, the chemical reaction of which is to be monitored. In order to follow the progress of the process, the concentration of the substance and the distribution thereof in the container 17 is to be determined. The concentration can be determined with the aid of light absorption of the liquid 18. In order to determine the light absorption, an integrated sensor chip unit 1₄ has at least one light-emitting diode 19 with a specific wavelength. The emitted radiation of the light-emitting diode 19 is received by a photodiode 20. Situated between the emitting light-emitting diode 19 and the receiving photodiode 20 is an interspace in which the liquid 18 to be monitored circulates. The interspace may be referred to as absorption path 21. The amount of light received by the photodiode 20 depends on the absorption of the circulating liquid 18 along the absorption path 21 at the wavelength of response of the photodiode 20.

The light-emitting diode 19 and the photodiode 20 are integrated, in the manner already described with regard to the other embodiments, with the aid of microsystems engineering on a semiconductor circuit module 22 containing the electronic conditioning circuit and also two coils 23 and 24 for the power supply and data exchange. The integrated semiconductor circuit module 22 drives inter alia the LEDs (light-emitting diode 19 and photodiode 20), conditions the measured values, and digitizes them. Of the coils 23 and 24 integrated in the semiconductor circuit module 22, coil 23 serves for power transmission and the coil 24 serves for data exchange and programming of the semiconductor circuit module 22. The entire integrated sensor chip unit 1₄ is provided with encapsulation 25 selected so that it is not attacked by the substances of the liquid 18 situated in the container 17.

A plurality of the integrated sensor chip units 1₄ may be arranged at different locations of the inner wall of the container 17. One or more receiving units 26 may be fitted to the outer side of the container 17. The receiving units 26 operate wirelessly and can read the integrated sensor chip units 1₄ in parallel or serially. The receiving units 26 contain two coils 27 and 28, of which coil 27 serves for power transmission and coil 28 serves for data exchange. An evaluation device, for example a computer 29, is connected to the receiving unit 26. The container 17 is composed of nonmetallic material at the installation locations for the integrated sensor chip units 1₄.

FIG. 5 shown another embodiment, demonstrating the incorporation of an integrated sensor chip unit 1₅. A pipeline system 30 serves to supply compressed air or a process gas. Through an increase in the number of consumption points in the system, the pressure may be reduced or pressure losses occur due to leakages in the system. Searching for these often proves to be very difficult and costly since each consumption station is examined manually. The problem point in the system can be narrowed down more rapidly by the installation of the pressure sensors. The components correspond to those from the embodiments described above, although the integrated sensor chip unit 1₅ is formed as a pressure sensor with an integrated evaluation circuit in accordance with the embodiments described above. A receiving unit 31 with a computer as an evaluation device 32 can be guided along the pipeline system 30 in order to read out the measured values of the respective integrated sensor chip units 1₅.

As shown in the embodiment in FIG. 5, the integrated sensor chip units can be introduced in the pipe wall as early as during the production thereof. As a result, the costs of the pipes increase only insignificantly since the production costs of the integrated sensor chip units are significantly less than the production costs that arise for the pipes themselves. Separate fixing of the integrated sensor chip units on the inner walls of the pipes can also be realized. In all applications, the integrated sensor chip units can be arranged at specific distances in the pipe, so that the evaluation unit can be guided along the outer wall of the pipe in order progressively to successively read all the relevant integrated sensor chip units.

Thus, as described, the sensor may be a biometric sensor such as a glucose sensor, a blood oxygen sensor or a light absorption sensor. The sensor can be a pressure sensor, a thermo sensor or a chemical sensor. The semiconductor circuit module may have components for power supply and a measured-value conditioning circuit, for example a digitization stage, for data exchange. The integrated sensor chip unit may be surrounded by an encapsulation. This encapsulation may permit the integrated sensor chip unit to be implanted into a human or other animal body and to be surrounded by bodily fluids. In addition, the integrated sensor chip unit can be integrated in walls of a pipeline system or other containers and can be used for process monitoring in containers with liquids. The power supply and the data exchange may be effected by means of a remotely acting receiving unit, particularly if the remote action is based on inductive coupling.

It is therefore intended that the foregoing detailed description be regarded as illustrative rather than limiting, and that it be understood that it is the following claims, including all equivalents, that are intended to define the spirit and scope of this invention. Nor is anything in the foregoing description intended to disavow scope of the invention as claimed or any equivalents thereof.

We claim:

1. An integrated sensor chip unit comprising:
a measured-value pickup operative to determine measurement data;
a circuit arrangement operative to enable a wireless power supply and interrogation of the measurement data; and
an encapsulation surrounds the integrated sensor chip unit,
wherein the measured-value pickup is formed as an integratable sensor and the circuit arrangement is embodied as an integrated semiconductor circuit module, the sensor and the semiconductor circuit module mechanically and electrically conductively connected to one another using a microsystems engineering technology;
wherein the semiconductor circuit module further comprises a measured-value conditioning circuit with a digitization stage;
a pipe system having at least one pipe, the at least one pipe having wall portions defined between an inner diameter and an outer diameter; and
wherein the sensor chip unit is located entirely within a cavity located between the inner diameter and the outer diameter of the wall portions of the at least one pipe.

2. The integrated sensor chip unit of claim 1, wherein the encapsulation is comprised of materials that permit the integrated sensor chip unit to be implanted in human or animal bodies.

3. The integrated sensor chip unit of claim 1, wherein the encapsulation is comprised of materials that permit transport in bodily fluids.

4. The integrated sensor chip unit of claim 1, wherein the sensor comprises at least one of a biometric sensor, a glucose sensor, a blood oxygen sensor, a light absorption sensor, a pressure sensor, a thermo sensor, or a chemical sensor.

5. The integrated sensor chip of claim 1, wherein the at least one pipe serves to supply compressed air or process gas.

6. The integrated sensor chip unit of claim 1, wherein the integrated sensor chip is introduced into the cavity during the production of the at least one pipe.

7. An integrated sensor chip unit comprising:
means for determining measurement data;
means for enabling a wireless power supply and interrogation of the measurement data that is mechanically and electrically conductively connected to the determining means using microsystems engineering means; and
the means for enabling the wireless power supply and interrogation of the measurement data further comprises a measured-value conditioning circuit with a digitization stage;
a pipe system having at least one pipe, the at least one pipe having wall portions defined between an inner diameter and an outer diameter; and
wherein the sensor chip unit is located entirely within a cavity located between the inner diameter and the outer diameter of the wall portions of the at least one pipe.

8. The integrated sensor chip unit of claim 7, wherein the enabling and interrogation means comprises means for effecting power supply and data exchange.

9. The integrated sensor chip unit of claim 7, wherein the means for effecting power supply and data exchange comprises means for inductive coupling.

10. The integrated sensor chip unit of claim 7, further comprising means for permitting the integrated sensor chip unit to be at least one of implanted in an animal body or transported in bodily fluids.

11. The integrated sensor chip unit of claim 7, further comprising means for permitting the sensor chip unit to be integrated within the interior of walls of a pipeline system.

12. The integrated sensor chip unit of claim 7, wherein the at least one pipe serves to supply compressed air or process gas.

13. The integrated sensor chip of claim 7, wherein the integrated sensor chip is introduced into the cavity during the production of the at least one pipe.
